(19) United States
(12) Patent Application Publication
(10) Pub. No.: US 2016/0372347 A1
(43) Pub. Date: Dec. 22, 2016

(54) SUBSTRATE PROCESSING APPARATUS

(71) Applicant: SAMSUNG ELECTRONICS CO., LTD., Suwon-si (KR)

(72) Inventors: Hyuk KIM, Seongnam-si (KR); Ha-Na KIM, Seoul (KR); Kyoungsub SHIN, Seongnam-si (KR); Jung-Ik OH, Hwaseong-si (KR)

(21) Appl. No.: 15/008,788

(22) Filed: Jan. 28, 2016

(30) Foreign Application Priority Data
Jun. 16, 2015 (KR) 10-2015-0085173

(51) Int. Cl. H01L 21/67

(52) U.S. Cl. CPC H01L 21/67069; H01L 21/67253

(57) ABSTRACT

Provided are a substrate processing apparatus capable of performing a semiconductor process using a plasma and a method of forming a semiconductor device using the same. The substrate processing apparatus includes a process chamber, a high vacuum pump, an exhaust flow path between the high vacuum pump and the process chamber, and a vacuum valve in the exhaust flow path. The vacuum valve includes a first valve and a second valve having a smaller orifice than the first valve.

### CROSS-REFERENCE TO RELATED APPLICATION

This application claims priority under 35 U.S.C. §119 to Korean Patent Application No. 10-2015-0085173 filed on Jun. 16, 2015 in the Korean Intellectual Property Office, the disclosure of which is hereby incorporated by reference in its entirety.

### BACKGROUND

1. Technical Field

Embodiments relate to a substrate processing apparatus capable of performing a semiconductor process using a plasma and a method of forming a semiconductor device using the same.

2. Description of Related Art

The semiconductor device manufacturing process using the plasma, for example, an etching process using the plasma is being used. The substrate processing apparatus for performing the plasma etching process includes the process chamber into which the semiconductor substrate is brought and processed, and the pumping system for forming the process chamber in a vacuum state.

### SUMMARY

In accordance with example embodiments, a substrate processing apparatus is provided. The substrate processing apparatus includes a process chamber, a high vacuum pump, an exhaust flow path disposed between the high vacuum pump and the process chamber, and a vacuum valve installed in the exhaust flow path. The vacuum valve includes a first valve and a second valve having a smaller orifice than the first valve.

In some embodiments, the substrate processing apparatus may further include a low vacuum pump, a foreline disposed between the high vacuum pump and the low vacuum pump, and a low vacuum valve disposed in the foreline.

In some embodiments, the first valve may include a first door and a first actuator which moves the first door, and the second valve may include a second door and a second actuator which moves the second door.

In some embodiments, the first and second actuators may be disposed under the first and second doors, respectively.

In some embodiments, the substrate processing apparatus may further include an auxiliary flow path passing through the first door, and the first valve may open and close the exhaust flow path, and the second valve may be installed in the auxiliary flow path and open and close the auxiliary flow path.

In some embodiments, the auxiliary flow path may pass through a center portion of the first door.

In some embodiments, the first door may be disposed at a center portion of a lower portion of the process chamber.

In some embodiments, the first valve and the second valve may be arranged in parallel.

In some embodiments, the substrate processing apparatus may further include a pressure detector which detects a pressure in the process chamber, and a vacuum valve control system which controls the vacuum valve.

In some embodiments, the substrate processing apparatus may further include a buffer chamber connected to the process chamber, and a low vacuum pump connected to the buffer chamber.

In accordance with example embodiments, a substrate processing apparatus includes a process chamber, a high vacuum pump, an exhaust flow path disposed between the high vacuum pump and the process chamber, and a vacuum valve installed in the exhaust flow path. The vacuum valve includes a door disposed in the exhaust flow path, and a first actuator and a second actuator, which are connected to the door and operate the door.

In some embodiments, the second actuator may operate the door to a lesser extent than the first actuator.

In some embodiments, the door may share one rod with the first and second actuators.

In some embodiments, the substrate processing apparatus may further include a pressure detector which detects an internal pressure of the process chamber, and a vacuum control system connected to the pressure detector and the vacuum control system may include a first actuator controller connected to the first actuator and a second actuator controller connected to the second actuator.

In some embodiments, the substrate processing apparatus may further include a low vacuum pump, a foreline which connects the low vacuum pump to the high vacuum pump, and a low vacuum valve disposed in the foreline.

In accordance with example embodiments, a substrate processing apparatus includes a process chamber, a high vacuum pump, an exhaust flow path disposed between the process chamber and the high vacuum pump, a high vacuum valve disposed in the exhaust flow path, a low vacuum pump, a foreline disposed between the low vacuum pump and the high vacuum pump, a low vacuum valve disposed in the foreline, a bypass line disposed between the high vacuum valve and the low vacuum valve, and a bypass valve disposed in the bypass line.

In some embodiments, one end of the bypass line may be connected to an exhaust line disposed between the high vacuum valve and the high vacuum pump, and the other end of the bypass line may be connected to the foreline disposed between the high vacuum pump and the low vacuum pump.

In some embodiments, the bypass line may be disposed inside a body of the high vacuum pump.

In some embodiments, the high vacuum valve may include a door which opens and closes the exhaust flow path, a rod connected to the door, an actuator which is connected to the rod and moves the door, and an actuator support which is connected to the actuator and fixes the actuator.

In some embodiments, the bypass line may be spaced apart from the high vacuum pump.

### BRIEF DESCRIPTION OF THE DRAWINGS

The foregoing and other features and advantages of embodiments will be apparent from the more particular description of preferred embodiments, as illustrated in the accompanying drawings in which like reference characters refer to the same parts throughout the different views. The drawings are not necessarily to scale, emphasis instead being placed upon illustrating the principles embodiments. In the drawings:

FIG. 1 is a view showing a substrate processing apparatus in accordance with an example embodiment;

FIG. 2 is a view showing an example of a substrate processing apparatus in accordance with an example embodiment;

FIG. 3 is a view showing a substrate processing apparatus in accordance with an example embodiment;

FIG. 4 is a view showing an example of a substrate processing apparatus in accordance with an example embodiment;

FIG. 5 is a view showing an example of a substrate processing apparatus in accordance with an example embodiment;

FIG. 6 is a view showing a substrate processing apparatus in accordance with an example embodiment;

FIG. 7 is a view showing an example of a substrate processing apparatus in accordance with an example embodiment;

FIG. 8 is a view showing a substrate processing apparatus in accordance with an example embodiment;

FIG. 9 is a view showing an example of a substrate processing apparatus in accordance with an example embodiment;

FIG. 10 is a view showing a substrate processing apparatus in accordance with an example embodiment;

FIG. 11 is a view showing an example of a substrate processing apparatus in accordance with an example embodiment;

FIG. 12 is a flowchart showing a method of forming a semiconductor device by performing a semiconductor process using any one of the substrate processing apparatuses according to the example embodiments;

FIG. 13 is a flowchart showing an example of performance of an etching process in FIG. 12; and

FIG. 14 is a graph showing a change of pressure in a process chamber in which an etching process is performed.

### DETAILED DESCRIPTION OF THE EMBODIMENTS

Embodiments may, however, be embodied in various different forms, and should be construed as limited, not by the embodiments set forth herein, but only by the accompanying claims. Rather, these embodiments are provided so that this disclosure is thorough and complete and fully conveys the embodiments to those skilled in the art. In the drawings, the sizes and relative sizes of layers and regions may be exaggerated for clarity. The same reference symbols denote the same components throughout the specification.

Embodiments are described herein with reference to cross-sectional views, plan views, and/or block diagrams that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. Therefore, regions illustrated in the drawings are schematic in nature, and their shapes are not intended to be limiting but only to illustrate characteristic forms of regions of devices.

The thicknesses of layers and regions in the drawings may be exaggerated for the sake of clarity. Further, it will be understood that when a layer is referred to as being “on” another layer or a substrate, the layer may be formed directly on the other layer or the substrate, or there may be an intervening layer therebetween. The same reference numerals indicate the same components throughout the specification.

Terms such as “top,” “bottom,” “upper,” “lower,” “above,” “below,” and the like are used herein to describe the relative positions of elements or features. It will be understood that such descriptions are intended to encompass different orientations in use or operation in addition to orientations depicted in the drawings. For example, when an upper part of a drawing is referred to as a “top” and a lower part of a drawing as a “bottom” for the sake of convenience, in practice, the “top” may also be called a “bottom” and the “bottom” a “top”.

Furthermore, throughout this disclosure, directional terms such as “upper,” “intermediate,” “lower,” and the like may be used herein to describe the relationship of one element or feature with another, and the embodiments should not be limited by these terms. Accordingly, these terms such as “upper,” “intermediate,” “lower,” and the like may be replaced by other terms such as “first,” “second,” “third,” and the like to describe the elements and features.

It will be understood that, although the terms “first,” “second,” etc. may be used herein to describe various elements, these elements should not be limited by these terms. These terms are only used to distinguish one element from another. Thus, a first element could be termed a second element.

The terminology used herein to describe embodiments is not intended to be limiting.

As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

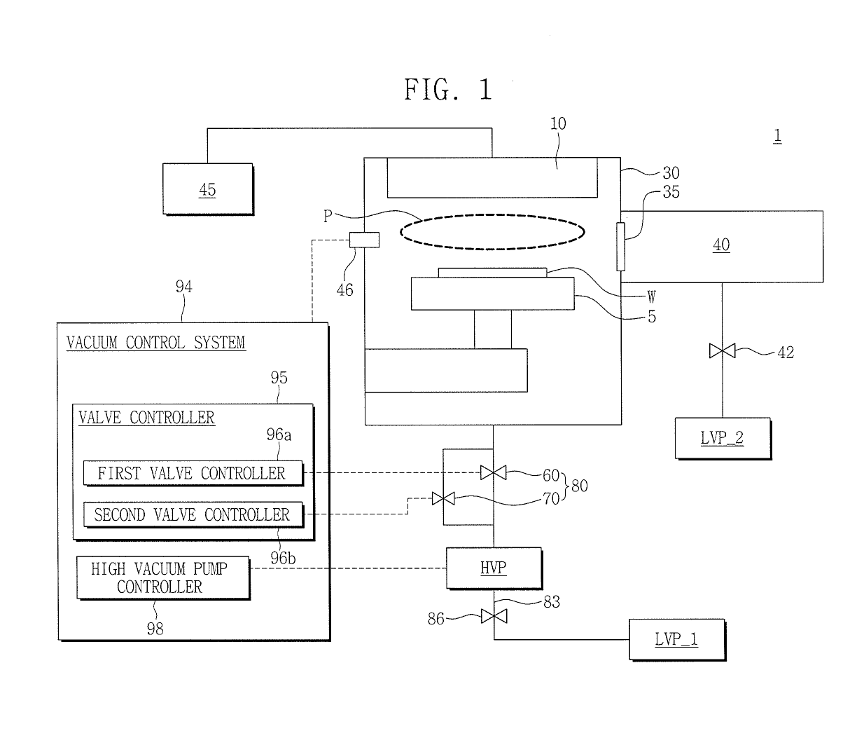

FIG. 1 is a view showing a substrate processing apparatus 1 in accordance with an example embodiment. The substrate processing apparatus 1 in accordance with an embodiment will be described with reference to FIG. 1.

Referring to FIG. 1, the substrate processing apparatus 1 in accordance with an embodiment may include a process chamber 30, a buffer chamber 40, a high vacuum pump HVP, a first low vacuum pump LVP_1, a second low vacuum pump LVP_2, a high vacuum valve 80, a first low vacuum valve 86, a second low vacuum valve 42, a process gas supply device 45, a pressure detector 46, and a vacuum control system 94.

The process chamber 30 may be a process chamber in which a semiconductor device manufacturing process may be performed using a plasma P. For example, the process chamber 30 may be a process chamber in which a plasma etching process may be performed.

The process chamber 30 may include a lower device 5 and an upper device 10, which are facing each other, with a space interposed therebetween, in which the plasma P may be formed. The upper device 10 of the process chamber 30 may include an upper electrode, a shower head, or a shower plate. The lower device 5 of the process chamber 30 may include a substrate support, on which a semiconductor substrate W may be located, for example, an electrostatic chuck.

The process gas supply device 45 may be connected to the process chamber 30. The process gas supply device 45 may be a device capable of supplying process gases for performing a plasma process.

The buffer chamber 40 may be connected to the process chamber 30. A gate 35 in which the semiconductor substrate W may enter and exit may be disposed between the buffer chamber 40 and the process chamber 30.

The high vacuum pump HVP may be disposed under the process chamber 30. The high vacuum pump HVP may be a pump capable of forming the process chamber 30 in a high vacuum state. For example, the high vacuum pump HVP may be a turbo molecular pump.

The high vacuum valve 80 may be disposed between the high vacuum pump HVP and the process chamber 30. The high vacuum valve 80 may include a first valve 60 and a second valve 70 having a smaller orifice than the first valve 60.

In an embodiment, the first valve 60 and the second valve 70 may be arranged in parallel.

The vacuum control system 94 may include a valve controller 95 and a high vacuum pump controller 98.

The vacuum control system 94 may be connected to the pressure detector 46 capable of detecting a process pressure in the process chamber 30.

The valve controller 95 may include a first valve controller 96a capable of controlling the first valve 60 and a second valve controller 96b capable of controlling the second valve 70. The high vacuum pump controller 98 may control an operation of the high vacuum pump HVP.

The first low vacuum pump LVP_1 may be connected to the high vacuum pump HVP using a foreline 83. The first low vacuum valve 86 may be disposed in the foreline 83 disposed between the first low vacuum pump LVP_1 and the high vacuum pump HVP. The second low vacuum pump LVP_2 may be connected to the buffer chamber 40. The second low vacuum valve 42 may be disposed between the second low vacuum pump LVP_2 and the buffer chamber 40. Any one or both of the first and second low vacuum pumps LVP_1 and LVP_2 may be a dry pump or a rotary pump.

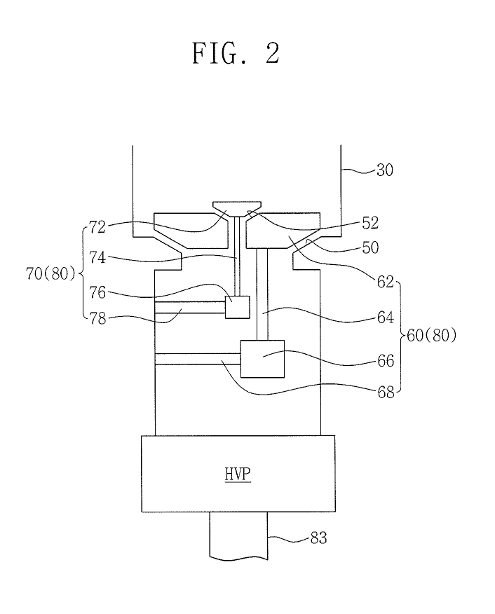

FIG. 2 is a view showing an example of the substrate processing apparatus 1 in accordance with an embodiment. An example of the high vacuum valve 80 of the substrate processing apparatus 1 will be described with reference to FIG. 2.

Referring to FIGS. 1 and 2, the high vacuum valve 80 may be disposed in an exhaust flow path 50 disposed between the process chamber 30 and the high vacuum pump HVP. The exhaust flow path 50 may be disposed on a lower portion of the process chamber 30.

The first valve 60 may open and close the exhaust flow path 50. The first valve 60 may include a first door 62, a first actuator 66, a first rod 64 which connects the first door 62 to the first actuator 66, and a first valve support 68 which supports the first actuator 66. The first door 62 of the first valve 60 may open and close the exhaust flow path 50 while the first door 62 of the first valve 60 moves by the driving of the first actuator 66. The first door 62 may be disposed at a center portion of the lower portion of the process chamber 30. The first rod 64 of the first valve 60 may be disposed eccentrically with respect to a center of the first door 62.

An auxiliary flow path 52 may be disposed to pass through the first door 62. The auxiliary flow path 52 may pass through a center portion of the first door 62.

The second valve 70 may open and close the auxiliary flow path 52. The second valve 70 may include a second door 72, a second actuator 76, a second rod 74 which connects the second door 72 to the second actuator 76, and a second valve support 78 which supports the second actuator 76. The second door 72 of the second valve 70 may open and close the auxiliary flow path 52 while the second door 72 of the second valve 70 moves by the driving of the second actuator 76. The second rod 74 of the second valve 70 may be disposed to pass through the auxiliary flow path 52.

Since the first valve 60 has a large orifice, the first valve 60 may operate so that pressure of the inside of the process chamber 30 may be significantly changed, and since the second valve 70 has a small orifice, the second valve 70 may operate so that the pressure of the inside of the process chamber 30 may be slightly changed.

When the pressure of the inside of the process chamber 30 is rapidly and quickly changed, the first valve 60 among the first and second valves 60 and 70 may be used to change the pressure as quickly as possible by significantly changing the pressure of the inside of the process chamber 30, and the second valve 70 may be used to quickly stabilize the pressure of the inside of the process chamber 30 by slightly changing the pressure.

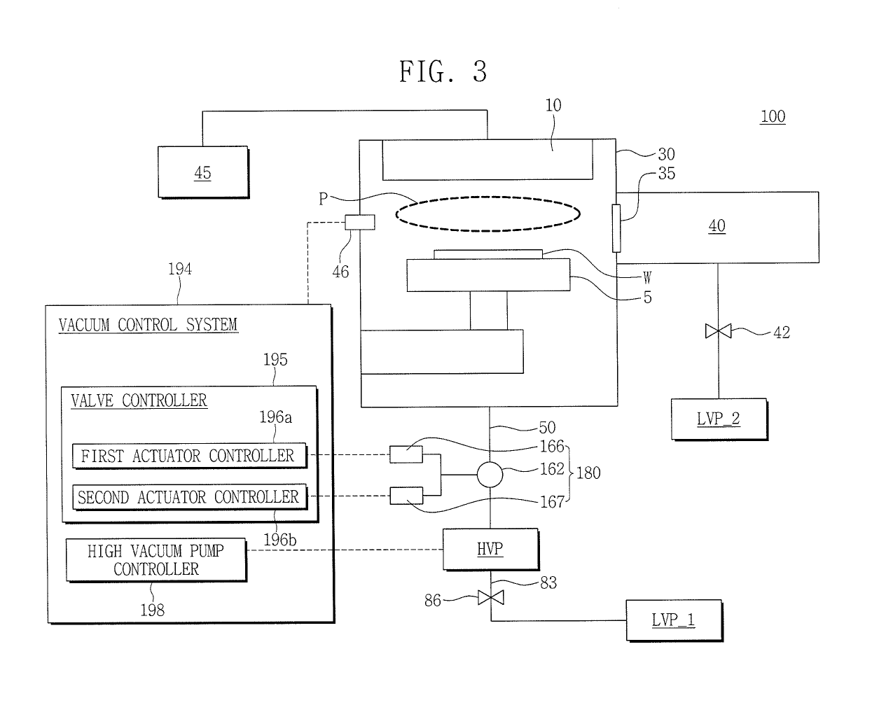

FIG. 3 is a view showing a substrate processing apparatus 100 in accordance with an embodiment. The substrate processing apparatus 100 in accordance with an embodiment will be described with reference to FIG. 3.

Referring to FIG. 3, the substrate processing apparatus 100 in accordance with an example embodiment may include the process chamber 30, the buffer chamber 40, the high vacuum pump HVP, the first low vacuum pump LVP_1, the second low vacuum pump LVP_2, the first low vacuum valve 86, the second low vacuum valve 42, the pressure detector 46, and the process gas supply device 45, which are included in the substrate processing apparatus 1 as described in FIG. 1.

The substrate processing apparatus 100 in accordance with an example embodiment may include a high vacuum valve 180 disposed between the high vacuum pump HVP and the process chamber 30, and a vacuum control system 194 connected to the high vacuum valve 180 and the pressure detector 46.

The high vacuum valve 180 may include a door 162, and a first actuator 166 and a second actuator 167, which are connected to the door 162.

The vacuum control system 194 may include a valve controller 195 which controls the high vacuum valve 180, and a high vacuum pump controller 198 which controls the high vacuum pump HVP. The valve controller 195 may include a first actuator controller 196a which controls the first actuator 166, and a second actuator controller 196b which controls the second actuator 167.

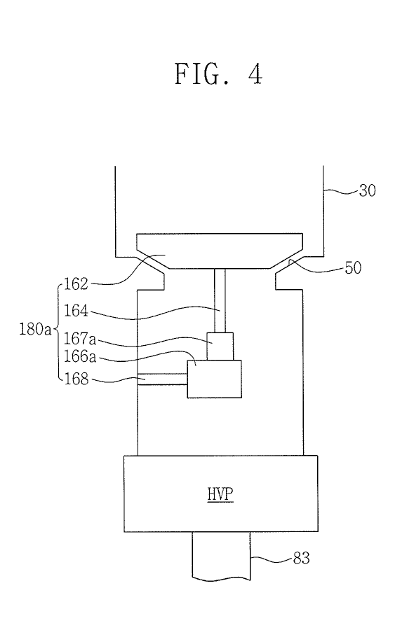

FIG. 4 is a view showing an example of the substrate processing apparatus 100 in accordance with an example embodiment. An example (180a) of the high vacuum valve 180 of the substrate processing apparatus 100 will be described with reference to FIG. 4.

Referring to FIGS. 3 and 4, the high vacuum valve 180a may include a door 162, a first actuator 166a, a second actuator 167a, a rod 164, and a valve support 168.

The second actuator 167a may be disposed on the first actuator 166a. The rod 164 may be disposed between the door 162 and the first and second actuators 166a and 167a. The door 162 may share the one rod 164 with the first and second actuators 166a and 167a.

The first and second actuators 166a and 167a may open and close an exhaust flow path 50 disposed between the process chamber 30 and the high vacuum pump HVP by moving the door 162. The second actuator 167a may move the door 162 to a lesser extent than the first actuator 166a.

Since the first actuator 166a significantly moves the door 162 and the second actuator 167a slightly moves the door 162, the first actuator 166a may operate so that the pressure of the inside of the process chamber 30 may be significantly changed and the second actuator 167a may operate so that the pressure of the inside of the process chamber 30 may be slightly changed.

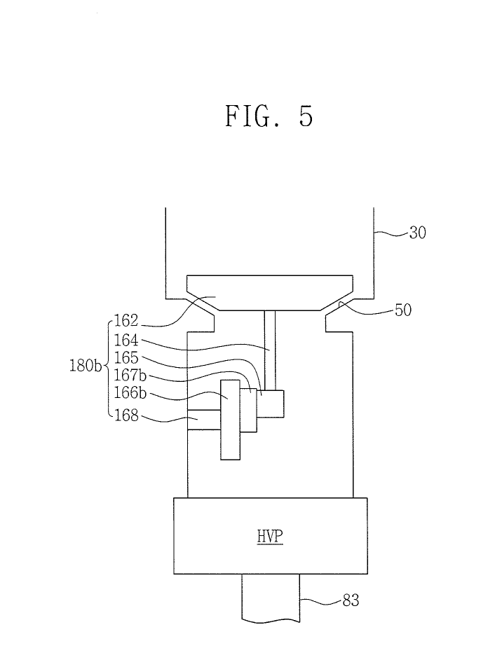

FIG. 5 is a view showing an example of the substrate processing apparatus 100 in accordance with an example embodiment. An example (180b) of the high vacuum valve 180 of the substrate processing apparatus 100 will be described with reference to FIG. 5.

Referring to FIGS. 3 and 5, the high vacuum valve 180b may include a door 162, a first actuator 166b, a second actuator 167b, a direction switching device 165, a rod 164, and a valve support 168.

In an embodiment, the first actuator 166b and the second actuator 167b may be disposed in parallel.

In an embodiment, the second actuator 167b may be disposed between the first actuator 166b and the direction switching device 165.

The door 162 may share the one rod 164 with the first and second actuators 166b and 167b.

The first and second actuators 166b and 167b may move the rod 164 through the direction switching device 165. The door 162 may vertically move according to the movement of the rod 164.

The first and second actuators 166b and 167b may open and close the exhaust flow path 50 disposed between the process chamber 30 and the high vacuum pump HVP by moving the door 162. The second actuator 167b may move the door 162 to a lesser extent than the first actuator 166b.

Since the first actuator 166b significantly moves the door 162 and the second actuator 167b may slightly move the door 162, the first actuator 166a may operate so that the pressure of the inside of the process chamber 30 may be significantly changed and the second actuator 167b may operate so that the pressure of the inside of the process chamber 30 may be slightly changed.

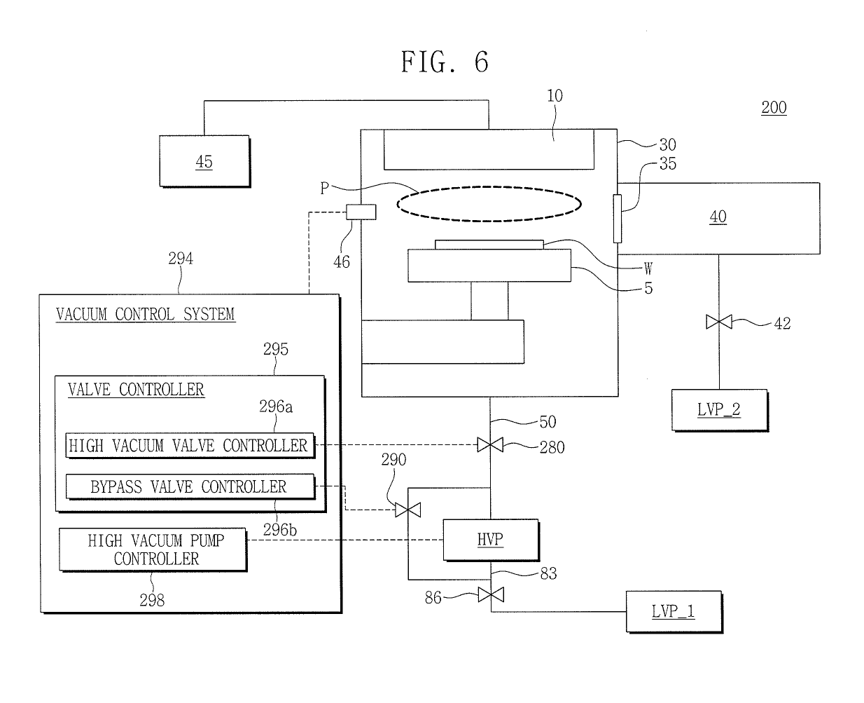

FIG. 6 is a view showing a substrate processing apparatus 200 in accordance with an example embodiment. The substrate processing apparatus 200 in accordance with an example embodiment will be described with reference to FIG. 6.

Referring to FIG. 6, the substrate processing apparatus 200 in accordance with an example embodiment may include the process chamber 30, the buffer chamber 40, the high vacuum pump HVP, the first low vacuum pump LVP_1, the second low vacuum pump LVP_2, the first low vacuum valve 86, the second low vacuum valve 42, the pressure detector 46, and the process gas supply device 45, which are included in the substrate processing apparatus 1 as described in FIG. 1.

The substrate processing apparatus 200 in accordance with an example embodiment may include a high vacuum valve 280, a bypass valve 290, and a vacuum control system 294.

The high vacuum valve 280 may be disposed or installed in the exhaust flow path 50 disposed between the high vacuum pump HVP and the process chamber 30.

The bypass valve 290 may be spaced apart from the high vacuum pump HVP. The bypass valve 290 may be disposed in a bypass flow path, which is connected to the exhaust flow path 50 located between the high vacuum pump HVP and the high vacuum valve 280 and the foreline 83 located between the high vacuum pump HVP and the first low vacuum pump LVP_1.

The vacuum control system 294 may include a valve controller 295, which controls the high vacuum valve 280 and the bypass valve 290, and a high vacuum pump controller 298 which controls the high vacuum pump HVP.

The valve controller 295 may include a high vacuum valve controller 296a which controls the high vacuum valve 280, and a bypass valve controller 296b which controls the bypass valve 290.

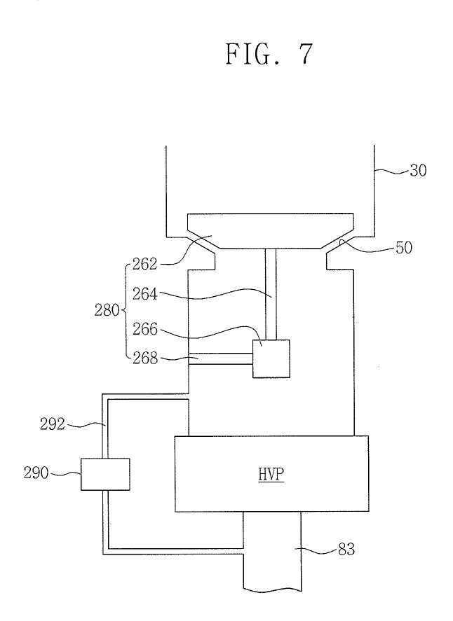

FIG. 7 is a view showing an example of the substrate processing apparatus 200 in accordance with an example embodiment. An example of the high vacuum valve 280 and the bypass valve 290 of the substrate processing apparatus 200 will be described with reference to FIG. 7.

Referring to FIGS. 6 and 7, the high vacuum valve 280 may be disposed in the exhaust flow path 50 disposed between the process chamber 30 and the high vacuum pump HVP. The high vacuum valve 280 may include a door 262, an actuator 266, a rod 264 which connects the door 262 to the actuator 266, and a valve support 268 which is connected to the actuator 266 and fixes the actuator 266.

The door 262 of the high vacuum valve 280 may open and close the exhaust flow path 50 while the door 262 of the high vacuum valve 280 moves by the driving of the actuator 266.

A bypass flow path 292 may be disposed to be connected to a portion of the exhaust flow path 50 located between the high vacuum pump HVP and the door 262 of the high vacuum valve 280 and a portion of the foreline 83 located between the high vacuum pump HVP and the first low vacuum valve 86 for the first low vacuum pump LVP_1.

In an embodiment, the bypass flow path 292 may be spaced apart from the high vacuum pump HVP. The bypass flow path 292 may be arranged in parallel to the high vacuum pump HVP. The bypass valve 290 may be disposed or installed in the bypass flow path 292.

When the pressure of the inside of the process chamber 30 is rapidly changed while a plurality of etching processes are performed in the process chamber 30, the pressure of the inside of the process chamber 30 may be quickly stabilized by adjusting the bypass valve 290.

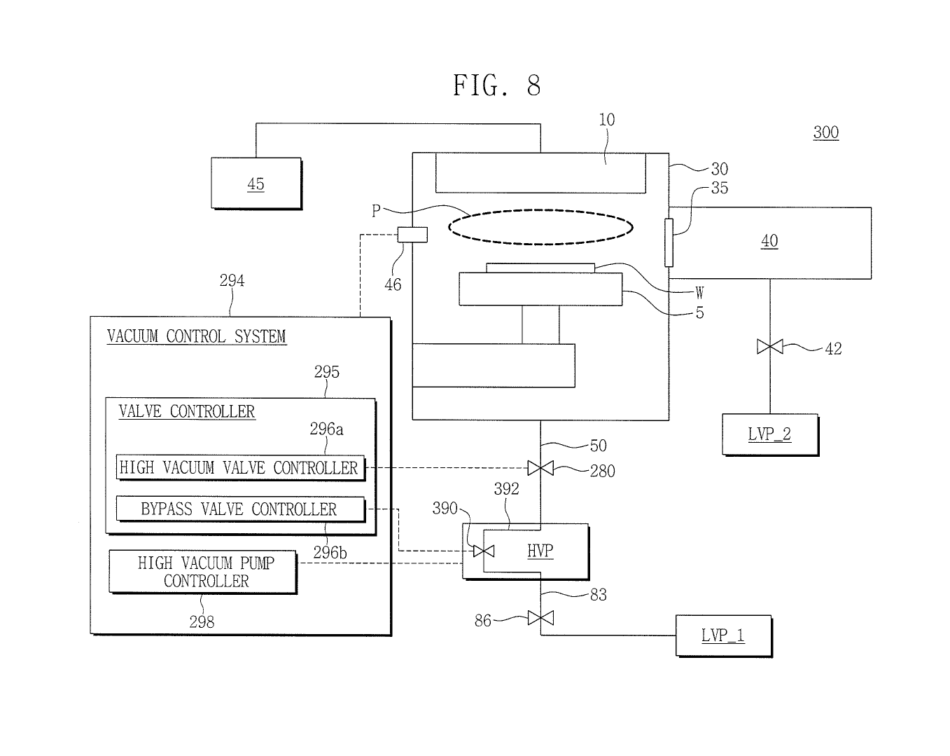

FIG. 8 is a view showing a substrate processing apparatus 300 in accordance with an example embodiment. The substrate processing apparatus 300 in accordance with an example embodiment will be described with reference to FIG. 8.

Referring to FIG. 8, the substrate processing apparatus 300 in accordance with an example embodiment may include the process chamber 30, the buffer chamber 40, the high vacuum pump HVP, the first low vacuum pump LVP_1, the second low vacuum pump LVP_2, the first low vacuum valve 86, the second low vacuum valve 42, the high vacuum valve 280, the pressure detector 46, and the process gas supply device 45, which are included in the substrate processing apparatus 200 as described in FIGS. 6 and 7.

The substrate processing apparatus 300 in accordance with an example embodiment may include a bypass flow path 392, a bypass valve 390, and a vacuum control system 294.

The vacuum control system 294 may include a valve controller 295 which controls the high vacuum valve 280 and the bypass valve 390, and a high vacuum pump controller 298 which controls the high vacuum pump HVP.

The valve controller 295 may include a high vacuum valve controller 296a which controls the high vacuum valve 280, and a bypass valve controller 296b which controls the bypass valve 390.

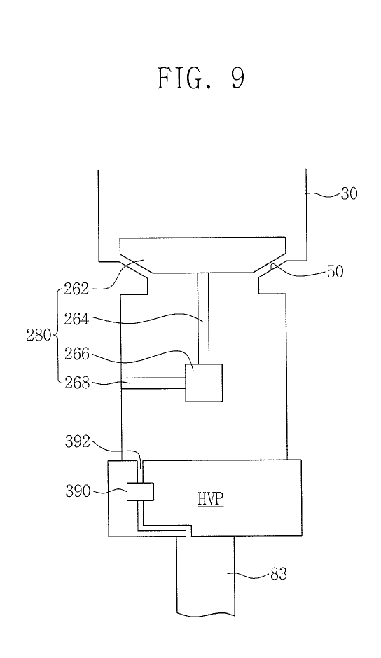

FIG. 9 is a view showing an example of a substrate processing apparatus 300 in accordance with an example embodiment. An example of the bypass flow path 392 and the bypass valve 390 of the substrate processing apparatus 300 will be described with reference to FIG. 9.

Referring to FIGS. 8 and 9, the bypass flow path 392 may be disposed inside the high vacuum pump HVP. The bypass valve 390 may be disposed in the bypass flow path 392. The bypass valve 390 may be disposed inside the high vacuum pump HVP.

When the pressure of the inside of the process chamber 30 is rapidly changed while a plurality of etching processes are performed in the process chamber 30, the pressure of the inside of the process chamber 30 may be quickly stabilized by adjusting the bypass valve 390.

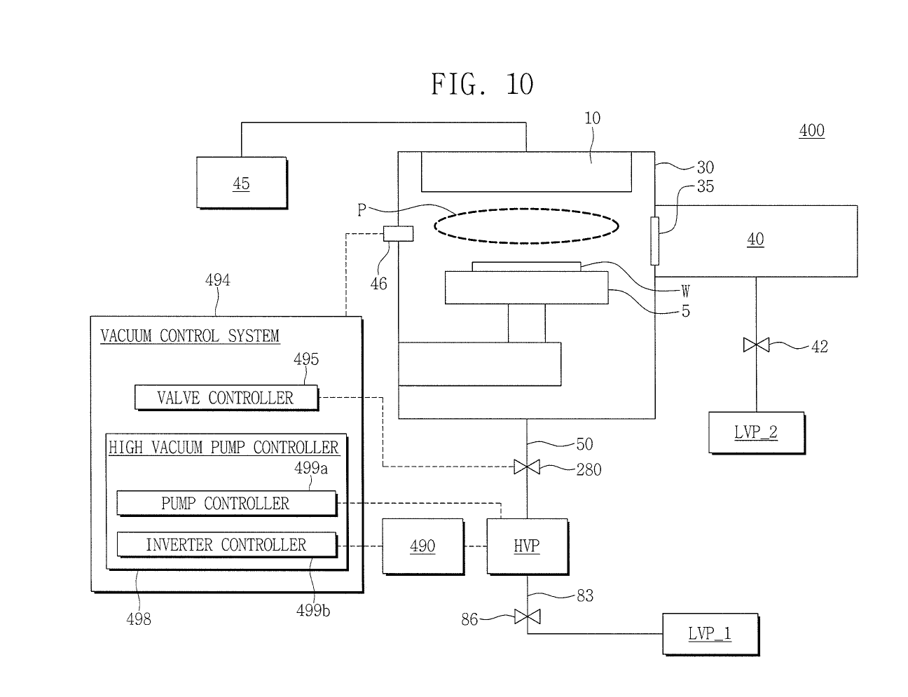

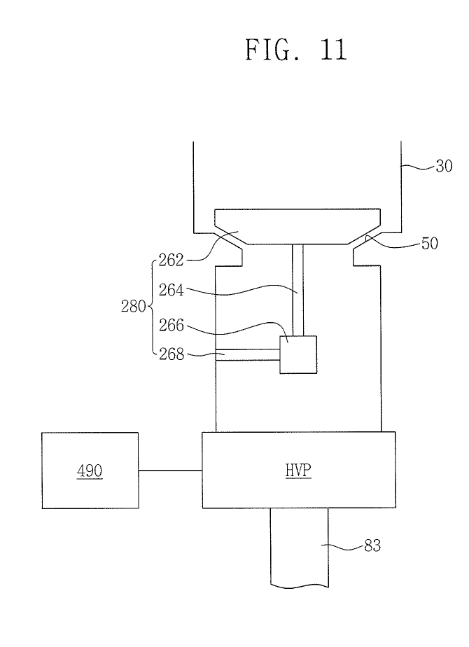

FIG. 10 is a view showing a substrate processing apparatus 400 in accordance with an example embodiment. FIG. 11 is a view showing an example of the substrate processing apparatus 400 in accordance with an example embodiment. The substrate processing apparatus 400 in accordance with an example embodiment will be described with reference to FIGS. 10 and 11.

Referring to FIGS. 10 and 11, the substrate processing apparatus 400 in accordance with an example embodiment may include the process chamber 30, the buffer chamber 40, the high vacuum pump HVP, the first low vacuum pump LVP_1, the second low vacuum pump LVP_2, the first low vacuum valve 86, the second low vacuum valve 42, the high vacuum valve 280, the pressure detector 46, and the process gas supply device 45, which are included in the substrate processing apparatus 200 as described in FIGS. 6 and 7.

The substrate processing apparatus 400 in accordance with an example embodiment may include a variable speed inverter 490 connected to the high vacuum pump HVP, and a vacuum control system 494.

The high vacuum pump HVP may be a turbo molecular pump. The variable speed inverter 490 may change the rotational speed of the high vacuum pump HVP, for example, the turbo molecular pump, to adjust the pumping capacity of the high vacuum pump HVP.

The vacuum control system 494 may include a high vacuum valve controller 495 which controls the high vacuum valve 280, and a high vacuum pump controller 498 which controls the high vacuum pump HVP.

The high vacuum pump controller 498 may include a pump controller 499a which operates the high vacuum pump HVP, and an inverter controller 499b which controls the variable speed inverter 490.

When the pressure of the inside of the process chamber 30 is rapidly changed while a plurality of etching processes are performed in the process chamber 30, the pressure of the inside of the process chamber 30 may be quickly stabilized by operating the variable speed inverter 490 and adjusting the pumping capacity of the high vacuum pump HVP.

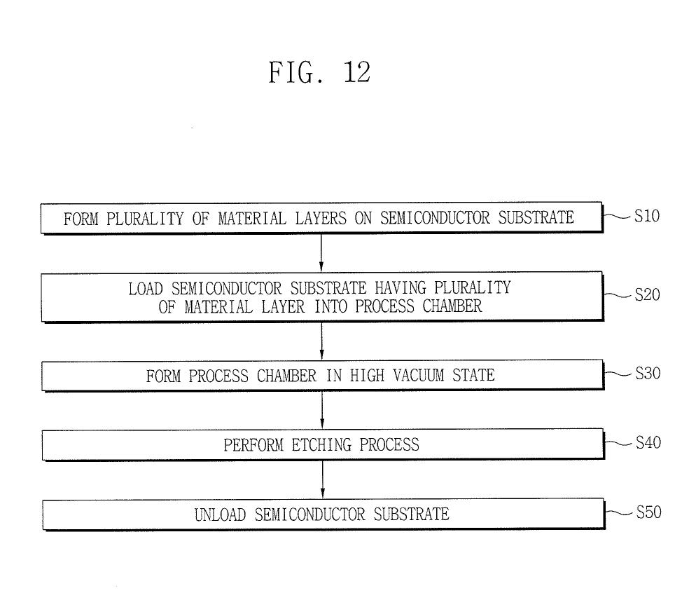

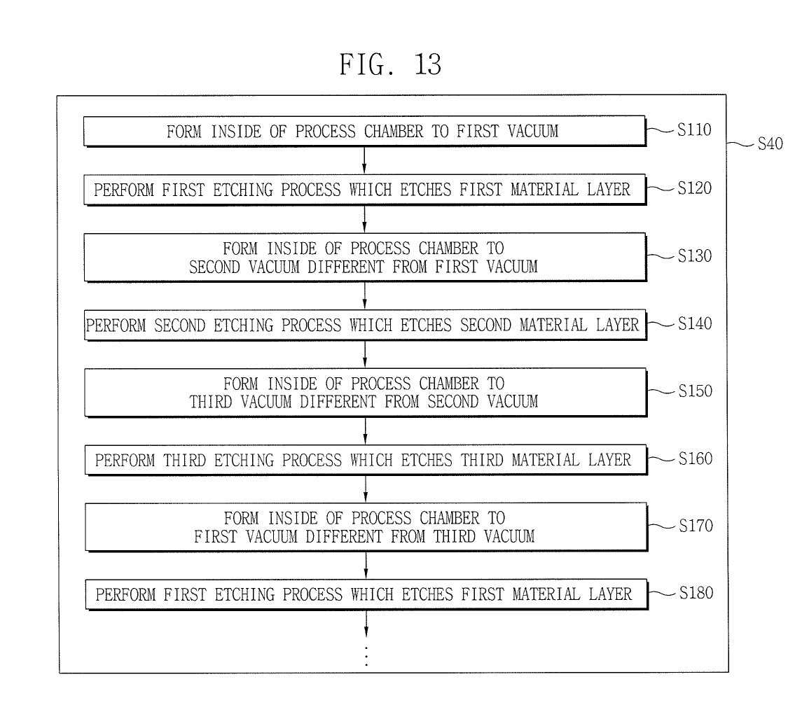

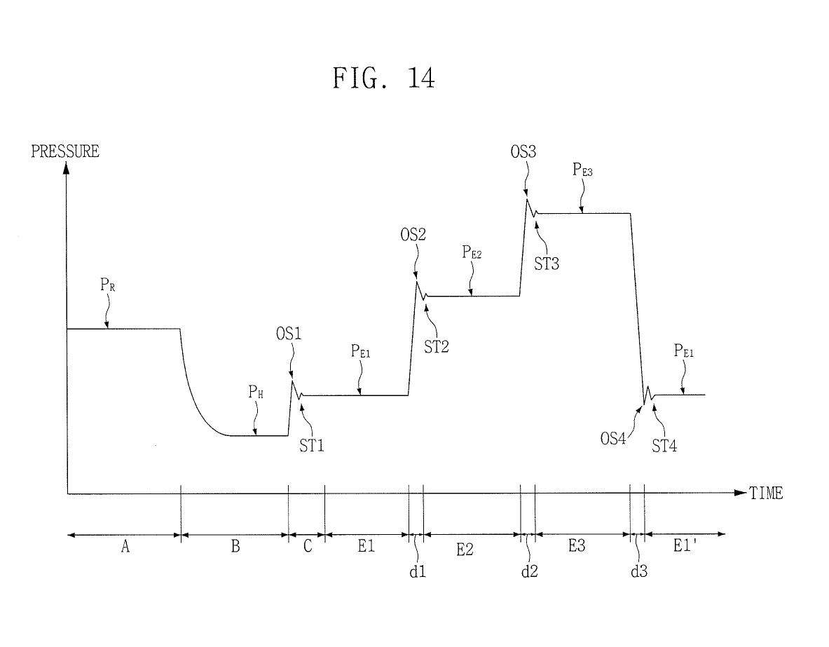

FIG. 12 is a flowchart showing a method of forming a semiconductor device by performing a semiconductor process using any one of the substrate processing apparatuses 1, 100, 200, 300, and 400 according to the example embodiments. FIG. 13 is a flowchart showing an example of performance of an etching process (S40) in FIG. 12. FIG. 14 is a graph showing a change of pressure in a process chamber 30 in which an etching process is performed.

First, the method of forming the semiconductor device by performing the semiconductor process using the substrate processing apparatus 1 in accordance with an embodiment will be described. The method of forming the semiconductor device using the substrate processing apparatus 1 shown in FIGS. 1 and 2 will be described with reference to FIGS. 12, 13, and 14.

Referring to FIGS. 1, 2, 12, 13, and 14, a plurality of material layers may be formed on a semiconductor substrate (S10 in FIG. 12). The plurality of material layers may include a first material layer, a second material layer, and a third material layer, which are different from each other. For example, the first material layer may be silicon oxide, the second material layer may be silicon nitride, and the third material layer may be a photoresist material.

The semiconductor substrate W having the plurality of material layers may be loaded into the process chamber 30 with a base vacuum P_{R} (S20 in FIG. 12 and A in FIG. 14). The semiconductor substrate W may be transferred and loaded into the process chamber 30 through the buffer chamber 40.

In an embodiment, the inside of the process chamber 30 with the base vacuum P_{R} may have a pressure of 10 mTorr.

When the semiconductor substrate W moves into the process chamber 30, the gate 35 disposed between the process chamber 30 and the buffer chamber 40 may open, and the buffer chamber 40 and the process chamber 30 may be in a base vacuum P_{R} state by the operation of the second low vacuum pump LVP_2 of the buffer chamber 40. Therefore, the semiconductor substrate W may be loaded into the process chamber 30 in the base vacuum P_{R} state. After the semiconductor substrate W is loaded into the process chamber 30, the gate 35 may close. The high vacuum pump HVP may be operated in order to quickly perform the semiconductor device manufacturing process, and the high vacuum valve 80 may be in a closed state.

The process chamber 30 with the base vacuum P_{R} may be formed in a high vacuum P_{H} state (S20 in FIG. 12 and B in FIG. 14).

The formation of the process chamber 30 with the base vacuum P_{R} in the high vacuum P_{H} state may include opening the high vacuum valve 80 in a state in which the high vacuum pump HVP operates. In this case, the first low vacuum pump LVP_1 may be in operation, and the first low vacuum valve 86 may be in an opened state. The pressure of the inside of the process chamber 30 in the high vacuum P_{H} state may be 10⁻⁵ Torr or less.

In an embodiment, the high vacuum valve 80 may maximally open in order to reduce the semiconductor device manufacturing process time. For example, both the first valve 60 and the second valve 70 of the high vacuum valve 80 may maximally open. Opening speeds of the first and second valves 60 and 70 may be controlled by the valve controller 95.

Next, an etching process may be performed (S40).

A method of performing the etching process will be described with reference to FIGS. 13 and 14.

Referring to FIGS. 1, 2, 13, and 14, the inside of the process chamber 30 may be formed with a first vacuum P_{E1} state (S110 in FIG. 13 and C in FIG. 14).

The formation of the inside of the process chamber 30 with the first vacuum P_{E1} state may include adjusting a degree of the opening of the high vacuum valve 80 while a process gas is introduced into the inside of the process chamber 30 in the high vacuum P_{H} state using the process gas supply device 45.

The adjusting of the degree of the opening of the high vacuum valve 80 may include providing information about a change of the pressure of the inside of the process chamber 30 to the vacuum control system 94 using the pressure detector 46, adjusting the degree of the opening of the high vacuum valve 80 through the valve controller 95 included in the vacuum control system 94, changing the pressure of the inside of the process chamber 30 according to the operation of the high vacuum valve 80, and providing information about the pressure of the inside of the process chamber 30 to the vacuum control system 94 using the pressure detector 46.

The first vacuum P_{E1} may be a vacuum, which is a higher vacuum than the base vacuum P_{R} and a lower vacuum than the high vacuum P_{H}. The pressure of the inside of the process chamber 30 in the first vacuum P_{E1} state may be lower than the pressure of the inside of the process chamber 30 in the base vacuum P_{R} state, but higher than the pressure of the inside of the process chamber 30 in the high vacuum P_{H} state.

When the inside of the process chamber 30 is changed from the high vacuum P_{H} to the first vacuum P_{E1}, a first overshooting portion OS1 and a first stabilizing portion ST1 may be generated.

The first overshooting portion OS1 may be a phenomenon in which the pressure of the inside of the process chamber 30 is more increased even after the pressure of the inside of the process chamber 30 is quickly increased and reaches the desired pressure. The first stabilizing portion ST1 may be a time in which the pressure of the inside of the process chamber 30 reaches the desired pressure in a stabilization stage after the first overshooting portion OS1.

After the pressure of the inside of the process chamber 30 is constant and is stabilized at the first vacuum P_{E1}, a first etching process which etches the first material layer may be performed (S120 in FIG. 13 and E1 in FIG. 14). The performance of the first etching process which etches the first material layer may include generating a plasma P and performing an etching process in the process chamber 30.

The supply of the process gas for performing the first etching process is stopped, the plasma generation power source is turned off, the plasma disappears, the first etching process is terminated, and then the inside of the process chamber 30 may be formed with a second vacuum P_{E2} different from the first vacuum P_{E1} (S130 in FIG. 13 and dl in FIG. 14).

The second vacuum P_{E2} may be a lower vacuum than the first vacuum P_{E1}. The pressure of the inside of the process chamber 30 in a second vacuum P_{E2} state may be higher than the pressure of the inside of the process chamber 30 in the first vacuum P_{E1} state.

In an embodiment, the second vacuum P_{E2} may be a lower vacuum than the base vacuum P_{R}. The pressure of the inside of the process chamber 30 in the second vacuum P_{E2} state may be higher than the pressure of the inside of the process chamber 30 in the base vacuum P_{R} state. The second vacuum P_{E2} may have pressure in a range of 30 mTorr to 70 mTorr.

The formation of the inside of the process chamber 30 with the second vacuum P_{E2} may include adjusting the high vacuum valve 80 while a process gas is supplied to the inside of the process chamber 30 using the process gas supply device 45.

In an embodiment, the adjusting of the high vacuum valve 80 may include finely adjusting a flow rate through the auxiliary flow path 52 while the second door 72 of the second valve 70 moves in a state in which the exhaust flow path 50 is not completely closed and is slightly open using the first valve 60.

When the inside of the process chamber 30 is changed from the first vacuum P_{E1} to the second vacuum P_{E2}, a second overshooting portion OS2 and a second stabilizing portion ST2 may be generated. In the second vacuum P_{E2} state in which the pressure is higher than that in the first vacuum P_{E1}, the second valve 70 of the high vacuum valve 80 may minimize the increasing of the second overshooting portion OS2 and the second stabilizing portion ST2. For example, when the inside of the process chamber 30 is changed from the first vacuum P_{E1} to the second vacuum P_{E2}, it is difficult to adjust only using the first valve 60, but the second overshooting portion OS2 and the second stabilizing portion ST2 may be minimized using the second valve 70 which may support the first valve 60 and finely move.

Next, a second etching process which etches the second material layer may be performed (S140 in FIG. 13 and E2 in FIG. 14).

The performance of the second etching process may include generating a plasma in the process chamber 30 and performing an etching process while a second process gas is supplied from the process gas supply device 45 into the process chamber 30.

The supply of the second process gas for performing the second etching process is stopped, the plasma generation power source is turned off, the plasma disappears, the second etching process is terminated, and then the inside of the process chamber 30 may be formed with a third vacuum P_{E3} different from the second vacuum P_{E2} (S150 in FIG. 13 and E3 in FIG. 14). The third vacuum P_{E3} may be a lower vacuum than the second vacuum P_{E2}. The pressure of the inside of the process chamber 30 in a third vacuum P_{E3} state may be higher than the pressure of the inside of the process chamber 30 in the second vacuum P_{E2} state.

The formation of the inside of the process chamber 30 with the third vacuum P_{E3} may include adjusting the high vacuum valve 80 while a process gas is supplied to the inside of the process chamber 30 using the process gas supply device 45.

In an embodiment, the adjusting of the high vacuum valve 80 may include finely adjusting a flow rate through the auxiliary flow path 52 while the second door 72 of the second valve 70 moves in a state in which the exhaust flow path 50 is not completely closed and is slightly open using the first valve 60.

When the inside of the process chamber 30 is changed from the second vacuum P_{E2} to the third vacuum P_{E3}, a third overshooting portion OS3 and a third stabilizing portion ST3 may be generated. In the third vacuum P_{E3} state in which the pressure is higher than that in the second vacuum P_{E2}, the second valve 70 of the high vacuum valve 80 may minimize the increasing of the third overshooting portion OS3 and the third stabilizing portion ST3. For example, when the inside of the process chamber 30 is changed from the second vacuum P_{E2} to the third vacuum P_{E3}, it is difficult to adjust only using the first valve 60, but the third overshooting portion OS3 and the third stabilizing portion ST3 may be minimized using the second valve 70 which may support the first valve 60 and finely move.

Next, a third etching process which etches the third material layer may be performed (S160 in FIG. 13 and E3 in FIG. 14). The performance of the third etching process may include generating a plasma in the process chamber 30, and performing an etching process while a third process gas is supplied from the process gas supply device 45 into the process chamber 30.

In the embodiments, the first vacuum P_{E1} may be a high vacuum having a lower pressure than the base vacuum PR, the second vacuum P_{E2} may be an intermediate vacuum having a higher pressure than the base vacuum P_{R}, and the third vacuum P_{E3} may be a low vacuum having a higher pressure than the second vacuum P_{E2}. For example, the base vacuum P_{R} may have a pressure of 10 mTorr, the first vacuum P_{E1} may be a high vacuum having a lower pressure than the base vacuum P_{R}, the second vacuum P_{E2} may be an intermediate vacuum having a pressure in a range of 30 mTorr to 70 mTorr, and the third vacuum P_{E3} may be a low vacuum having a higher pressure than the second vacuum P_{E2}. For example, the second vacuum P_{E2} may have a pressure of 70 mTorr or more. For example, the third vacuum P_{E3} may have a pressure in a range of 70 mTorr to 300 mTorr. Here, embodiments are not limited to the “value” of the pressure in the base vacuum P_{R}, and the first to third vacuums P_{E1}, P_{E2}, and P_{E3}. For example, the pressure in the process chamber 30 of the base vacuum P_{R} is not limited to a value of 10 mTorr, and may be slightly changed according to the type of the substrate processing apparatus or the type of the process. The pressure in the first to third vacuums P_{E1}, P_{E2}, and P_{E3} may be slightly changed according to the type of the etching target material layers and the etching shape of the target to be etched. For example, when an isotropic etching process is performed in a plasma etching process, the process may be performed in the third vacuum P_{E3}, and when an anisotropic etching process is performed therein, the process may be performed in the first vacuum P_{E1} or the second vacuum P_{E2}.

Next, after the performance of the third etching process is completed, the inside of the process chamber 30 may be formed with the first vacuum P_{E1} different from the third vacuum P_{E3} (S170 in FIG. 13 and d3 in FIG. 14). While the inside of the process chamber 30 is changed from the third vacuum P_{E3} as a low vacuum to the first vacuum P_{E1} as a high vacuum, an overshooting portion OS4 and a fourth stabilizing portion ST4 may be generated.

Although a change from the third vacuum P_{E3} to the first vacuum P_{E1} is large, sizes of the fourth overshooting portion OS4 and the fourth stabilizing portion ST4 may be minimized by adjusting the first and second valves 60 and 70. For example, the pressure of the inside of the process chamber 30 is slightly changed by adjusting the second valve 70 while the pressure of the inside of the process chamber 30 is significantly changed by further opening the first valve 60, and thus, the fourth overshooting portion OS4 and the fourth stabilizing portion ST4 may be minimized.

Next, the first etching process which etches the first material layer may be performed again (S180 in FIG. 13 and E1′ in FIG. 14). As described above, after the first to third etching processes are performed, the semiconductor substrate W may be unloaded from the process chamber 30 (S50).

During the first to third etching processes, the pressure in the process chamber 30 may be changed from a low pressure to a high pressure. When the pressure is changed as described above, the first valve 60 among the first and second valves 60 and 70 may be used to change the pressure as quickly as possible by significantly changing the pressure, and the second valve 70 may be used to stably and quickly control the overshooting portions OS1, OS2, and OS3, and the stabilizing portions ST1, ST2, and ST3 of the pressure by slightly changing the pressure. Therefore, an overall etching process time may be reduced, the overshooting portions OS1, OS2, and OS3 and the stabilizing portions ST1, ST2, and ST3 may be minimized, and thus the process distribution may be minimized.

The etching process performed in the high vacuum, the etching process performed in the intermediate vacuum, and the etching process performed in the low vacuum may be quickly and stably performed using a pumping system including the high vacuum pump HVP and the high vacuum valve 80.

Although the method of forming the semiconductor device using the substrate processing apparatus 1 in accordance with an embodiment is described, the substrate processing apparatuses 100, 200, 300, and 400 according to the embodiments may be used as the substrate processing apparatus 1. Operation examples of the substrate processing apparatuses 100, 200, 300, and 400 will be described.

In an embodiment, the first actuator 166a of the high vacuum valve 180a described in FIGS. 3 and 4 may quickly change the pressure of the inside of the process chamber 30 by significantly moving the door 162, the second actuator 167a may slightly change the pressure of the inside of the process chamber 30 by slightly moving the door 162, and thus, the overshooting portions OS1, OS2, and OS3, and the stabilizing portions ST1, ST2, and ST3 of the pressure described in FIG. 14 may be stably and quickly controlled.

In an embodiment, the first actuator 166b of the high vacuum valve 180b described in FIGS. 3 and 5 may quickly change the pressure of the inside of the process chamber 30 by significantly moving the door 162, the second actuator 167b may slightly change the pressure of the inside of the process chamber 30 by slightly moving the door 162, and thus, the overshooting portions OS1, OS2, and OS3, and the stabilizing portions ST1, ST2, and ST3 of the pressure described in FIG. 14 may be stably and quickly controlled.

In an embodiment, the high vacuum valve 280 described in FIGS. 6 and 7 may quickly change the pressure of the inside of the process chamber 30, the bypass valve 290 may minimize the sizes of the overshooting portions OS1, OS2, and OS3 by opening immediately before the overshooting portions OS1, OS2, and OS3 of the pressure described in FIG. 14 are generated, and as a result, the stabilizing portions ST1, ST2, and ST3 may also be minimized. Therefore, the overshooting portions OS1, OS2, and OS3 and the stabilizing portions ST1, ST2, and ST3 of the pressure described in FIG. 14 may be stably and quickly controlled.

In an embodiment, the high vacuum valve 280 described in FIGS. 8 and 9 may quickly change the pressure of the inside of the process chamber 30, the bypass valve 390 may minimize the sizes of the overshooting portions OS1, OS2, and OS3 by opening immediately before the overshooting portions OS1, OS2, and OS3 of the pressure described in FIG. 14 are generated, and as a result, the stabilizing portions ST1, ST2, and ST3 may also be minimized. Therefore, the overshooting portions OS1, OS2, and OS3 and the stabilizing portions ST1, ST2, and ST3 of the pressure described in FIG. 14 may be stably and quickly controlled.

In an embodiment, the high vacuum valve 280 described in FIGS. 10 and 11 may quickly change the pressure of the inside of the process chamber 30, the variable speed inverter 490 may minimize the sizes of the overshooting portions OS1, OS2, and OS3 by reducing the speed of operation of the high vacuum pump HVP, for example, the rotational speed of the turbo molecular pump, and temporarily reducing the pumping capacity of the high vacuum pump HVP immediately before the overshooting portions OS1, OS2, and OS3 of the pressure described in FIG. 14 are generated, and as a result, the stabilizing portions ST1, ST2, and ST3 may also be minimized. Therefore, the overshooting portions OS1, OS2, and OS3 and the stabilizing portions ST1, ST2, and ST3 of the pressure described in FIG. 14 may be stably and quickly controlled.

Therefore, according to the embodiments, the etching process performed in the high vacuum, the etching process performed in the intermediate vacuum, and the etching process performed in the low vacuum may be quickly and stably performed using a pumping system disposed under the process chamber 30.

According to the embodiments, while the plurality of etching processes (S120, S140, and S160 in FIG. 13) for etching the different material layers are performed in the one process chamber 30, it is possible to provide the substrate processing apparatus including the pumping system capable of quickly and stably changing the pressure of the inside of the process chamber 30.

According to the embodiments, it is possible to perform the etching process in a stable environment while the process switching time between the plurality of etching processes is minimized.

According to the embodiments, the pressure in the process chamber 30 is quickly changed and also the stabilization time of the pressure is minimized, and thus the overall processing time may be reduced and the productivity may be improved. The pressure in the process chamber 30 is quickly stabilized, and thus the distribution characteristic in the etching process may be improved.

According to the embodiments, a substrate processing apparatus including a pumping system capable of quickly and stably changing the pressure in a process chamber while a plurality of etching processes are performed in one process chamber can be provided. For example, when a second etching process following a first etching process is performed, a process switching time between the first and second etching processes is minimized, and thus it is possible to perform the second etching process in a stable environment. Therefore, since the stabilization time of the pressure in the process chamber can be minimized, the overall processing time can be reduced and thus the productivity can be improved. Further, since the pressure in the process chamber can be quickly stabilized, the distribution characteristic in the etching process can be improved.

Although a few embodiments have been described, those skilled in the art will readily appreciate that many modifications are possible in embodiments without materially departing from the novel teachings and advantages. Accordingly, all such modifications are intended to be included within the scope of embodiments as defined in the claims.

What is claimed is:

1. A substrate processing apparatus, comprising:
a process chamber;
a high vacuum pump;
an exhaust flow path between the high vacuum pump and the process chamber; and
a vacuum valve in the exhaust flow path,
the vacuum valve including a first valve and a second valve, the second valve having a smaller orifice than the first valve.

2. The apparatus of claim 1, further comprising:
a low vacuum pump;
a foreline between the high vacuum pump and the low vacuum pump; and
a low vacuum valve in the foreline.

3. The apparatus of claim 1, wherein:
the first valve includes a first door and a first actuator to move the first door, and
the second valve includes a second door and a second actuator to move the second door.

4. The apparatus of claim 3, wherein the first and second actuators are under the first and second doors, respectively.

5. The apparatus of claim 3, further comprising an auxiliary flow path passing through the first door, the first valve to open and close the exhaust flow path, the second valve being in the auxiliary flow path, the second valve to open and close the auxiliary flow path.

6. The apparatus of claim 5, wherein the auxiliary flow path passes through a center portion of the first door.

7. The apparatus of claim 3, wherein the first door is at a center portion of a lower portion of the process chamber.

8. The apparatus of claim 1, wherein the first valve and the second valve are in parallel.

9. The apparatus of claim 1, further comprising:
a pressure detector to detect a pressure in the process chamber; and
a vacuum valve control system to control the vacuum valve.

10. The apparatus of claim 1, further comprising:
a buffer chamber connected to the process chamber; and
a low vacuum pump connected to the buffer chamber.

11. A substrate processing apparatus, comprising:
a process chamber;
a high vacuum pump;
an exhaust flow path between the high vacuum pump and the process chamber; and
a vacuum valve in the exhaust flow path,
the vacuum valve including a door in the exhaust flow path and a first actuator and a second actuator, the first and second actuators being connected to the door, the first and second actuators operating the door.

12. The apparatus of claim 11, wherein the second actuator operates the door to a lesser extent than the first actuator.

13. The apparatus of claim 11, wherein the door shares one rod with the first and second actuators.

14. The apparatus of claim 11, further comprising:
a pressure detector to detect an internal pressure of the process chamber; and
a vacuum control system connected to the pressure detector,
wherein the vacuum control system includes a first actuator controller connected to the first actuator and a second actuator controller connected to the second actuator.

15. The apparatus of claim 11, further comprising:
a low vacuum pump;
a foreline to connect the low vacuum pump to the high vacuum pump; and
a low vacuum valve in the foreline.

16. A substrate processing apparatus, comprising:
a process chamber;
a high vacuum pump;
an exhaust flow path between the process chamber and the high vacuum pump;
a high vacuum valve in the exhaust flow path;
a low vacuum pump;
a foreline between the low vacuum pump and the high vacuum pump;
a low vacuum valve in the foreline;
a bypass line between the high vacuum valve and the low vacuum valve; and
a bypass valve in the bypass line.

17. The apparatus of claim 16, wherein:
a first end of the bypass line is connected to the exhaust flow path between the high vacuum valve and the high vacuum pump, and
a second end of the bypass line is connected to the foreline between the high vacuum pump and the low vacuum pump.

18. The apparatus of claim 16, wherein the bypass line is inside a body of the high vacuum pump.

19. The apparatus of claim 16, wherein the high vacuum valve includes a door to open and close the exhaust flow path, a rod connected to the door, an actuator connected to the rod, the actuator to move the door, and an actuator support connected to the actuator, the actuator support to fix the actuator.

20. The apparatus of claim 16, wherein the bypass line is spaced apart from the high vacuum pump.
